(19) United States
(12) Patent Application Publication
(10) Pub. No.: US 2026/0033263 A1
(43) Pub. Date: Jan. 29, 2026

(54) CONFORMAL SELECTIVE ETCHING OF SILICON OXIDE

(71) Applicant: Applied Materials, Inc., Santa Clara, CA (US)

(72) Inventors: Mikhail Korolik, San Jose, CA (US); Zachary J. Devereaux, Webberville, MI (US); Thomas Joseph Knisley, Livonia, MI (US); Lisa J. Enman, Sunnyvale, CA (US)

(73) Assignee: Applied Materials, Inc., Santa Clara, CA (US)

(21) Appl. No.: 18/781,125

(22) Filed: Jul. 23, 2024

(51) Int. Cl. H01L 21/311

(52) U.S. Cl. CPC H01L 21/31116

(57) ABSTRACT

Exemplary semiconductor processing methods may include providing a catalyst precursor to a processing region of a semiconductor processing chamber. A substrate may be disposed within the processing region. The substrate may include a silicon-and-oxygen-containing material and one or more silicon-containing materials. The methods may include contacting the substrate with the catalyst precursor. The contacting may adsorb the catalyst precursor on the silicon-and-oxygen-containing material and/or the one or more silicon-containing materials. The methods may include providing an etchant precursor to the processing region. The methods may include contacting the substrate with the etchant precursor. The contacting may selectively remove the silicon-and-oxygen-containing material.

### TECHNICAL FIELD

The present technology relates to semiconductor processes and equipment. More specifically, the present technology relates to conformally etching materials relative to other materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a catalyst precursor to a processing region of a semiconductor processing chamber. A substrate may be disposed within the processing region. The substrate may include a silicon-and-oxygen-containing material and one or more silicon-containing materials. The methods may include contacting the substrate with the catalyst precursor. The contacting may adsorb the catalyst precursor on the silicon-and-oxygen-containing material and/or the one or more silicon-containing materials. The methods may include providing an etchant precursor to the processing region. The methods may include contacting the substrate with the etchant precursor. The contacting may selectively remove the silicon-and-oxygen-containing material.

In some embodiments, the catalyst precursor may be or include an alcohol. The catalyst precursor may be characterized by a vapor pressure of less than or about 100 Torr at a temperature between about 0° C. and about 30° C. The catalyst precursor may be or include isopropanol (C₃H₈O), 1-propanol (C₃H₇OH), isobutanol (C₄H₁₀O), ethenol (C₂H₄O), ethylene glycol (C₂H₆O₂), C₂F₄O₂H₂, fluorinated ethylene glycol, fluorinated isobutanol, fluorinated ethenol, or CF₂═CF—OH. The catalyst precursor may be metal-free. The silicon-containing materials may be or include silicon material, silicon-and-nitrogen-containing material, and silicon-and-germanium-containing material. The substrate may include a plurality of layers of the silicon-and-oxygen-containing material in alternation with a plurality of layers of the one or more silicon-containing materials. The etchant precursor may be or include a halogen-containing precursor. The etchant precursor may be or include hydrogen fluoride (HF) or HF-pyridinc. Removing the silicon-and-oxygen-containing material may be solid byproduct-free. Contacting the substrate with the etchant precursor may remove the silicon-and-oxygen-containing material relative to the one or more silicon-containing materials at a selectivity of greater than or about 3:1. The methods may include repeatedly contacting the substrate with the catalyst precursor and the etchant precursor to remove the silicon-and-oxygen-containing material on a layer-by-layer basis. A temperature within the processing region may be maintained at less than or about 150° C.

Some embodiments of the present technology may encompass semiconductor processing methods. The methods may include providing a catalyst precursor to a processing region of a semiconductor processing chamber. A substrate may be disposed within the processing region. The substrate may include a plurality of layers of silicon-and-oxygen-containing material in alternation with a plurality of layers of one or more silicon-containing materials. The plurality of layers of silicon-and-oxygen-containing material and the plurality of layers of one or more silicon-containing materials may define one or more features. The methods may include contacting the substrate with the catalyst precursor. The contacting may adsorb the catalyst precursor on the plurality of layers of silicon-and-oxygen-containing material and the plurality of layers of one or more silicon-containing materials. The methods may include halting a flow of the catalyst precursor. The methods may include providing an etchant precursor to the processing region. The methods may include contacting the substrate with the etchant precursor. The contacting may selectively remove the plurality of layers of silicon-and-oxygen-containing material uniformly along a length of the one or more features.

In some embodiments, the catalyst precursor may be characterized by a vapor pressure of less than or about 100 Torr at a temperature between about 0° C. and about 30° C. The one or more features may be characterized by a depth of greater than or about 2 μm. A temperature within the processing region may be maintained at less than or about 100° C.

Some embodiments of the present technology may encompass semiconductor processing methods. The methods may include providing a metal-free catalyst precursor comprising at least one hydrogen-containing functional group to a processing region of a semiconductor processing chamber. A substrate may be disposed within the processing region. The substrate may include a plurality of layers of silicon-and-oxygen-containing material in alternation with a plurality of layers of one or more silicon-containing materials. The plurality of layers of silicon-and-oxygen-containing material and the plurality of layers of one or more silicon-containing materials may define one or more features. The methods may include contacting the substrate with the metal-free catalyst precursor. The contacting may adsorb the metal-free catalyst precursor on the plurality of layers of silicon-and-oxygen-containing material and the plurality of layers of one or more silicon-containing materials. The methods may include halting a flow of the metal-free catalyst precursor. The methods may include providing a halogen-containing precursor to the processing region. The methods may include contacting the substrate with the halogen-containing precursor. The contacting may selectively remove the plurality of layers of silicon-and-oxygen-containing material uniformly along a length of the one or more features. The methods may include repeatedly contacting the substrate with the catalyst precursor and the halogen-containing precursor for a number of cycles to remove the plurality of layers of silicon-and-oxygen-containing material on a layer-by-layer basis.

In some embodiments, the one or more features may be characterized by an aspect ratio of greater than or about 5:1. An etch rate of the plurality of layers of silicon-and-oxygen-containing material may be greater than or about 0.05 angstrom per cycle (Å/cycle).

Such technology may provide numerous benefits over conventional systems and techniques. For example, the methods may conformally etch silicon oxide isotropically within semiconductor structures. Additionally, the methods may maintain other exposed silicon-containing materials during the etching. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

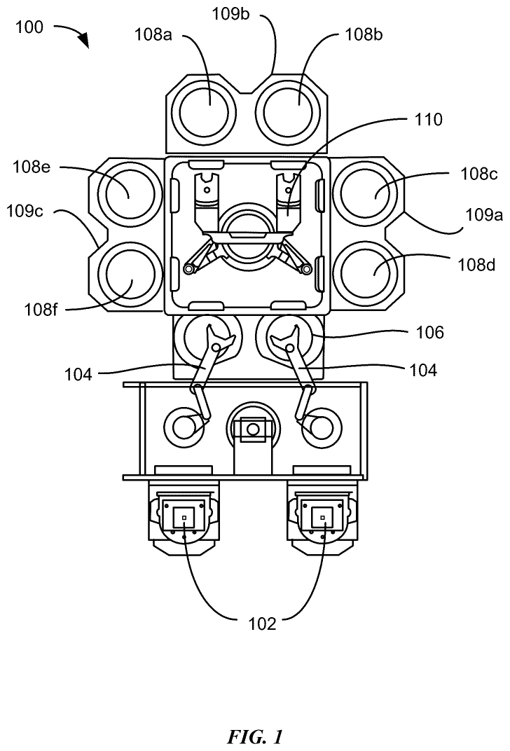

FIG. 1 shows a top plan view of one embodiment of an exemplary processing system according to some embodiments of the present technology.

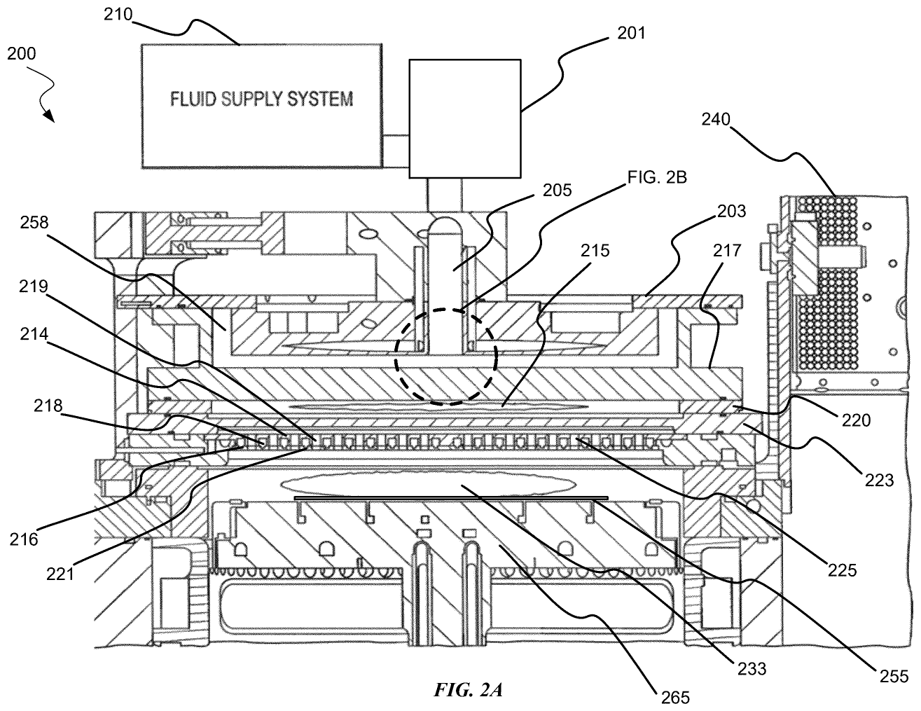

FIG. 2A shows a schematic cross-sectional view of an exemplary processing chamber according to some embodiments of the present technology.

FIG. 2B shows a detailed view of a portion of the processing chamber illustrated in FIG. 2A according to some embodiments of the present technology.

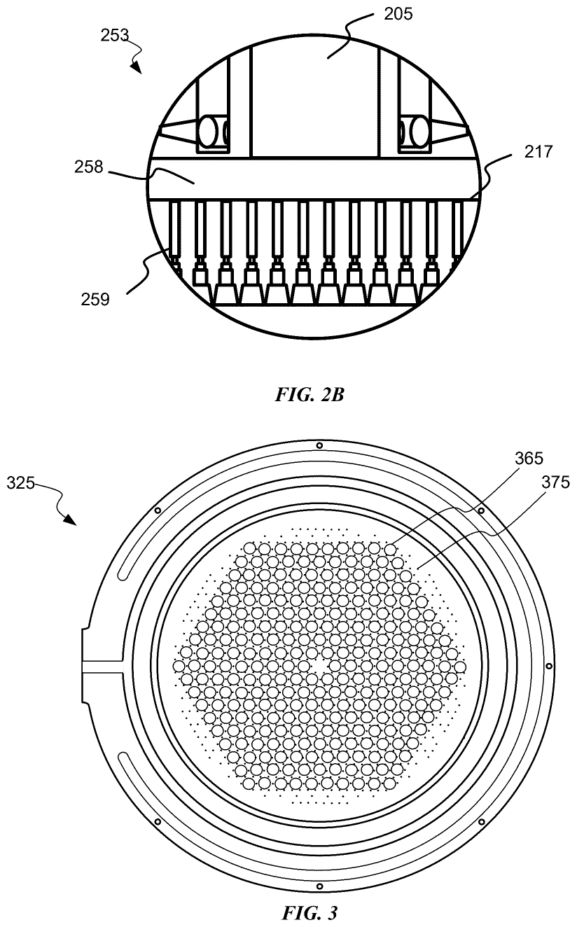

FIG. 3 shows a bottom plan view of an exemplary showerhead according to some embodiments of the present technology.

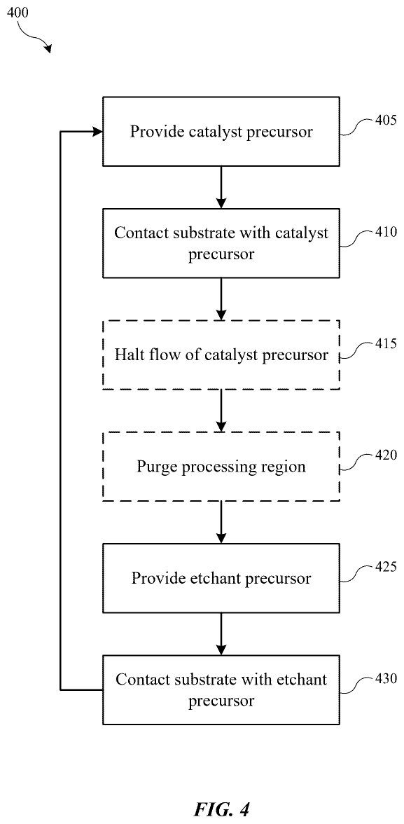

FIG. 4 shows exemplary operations in a method according to some embodiments of the present technology.

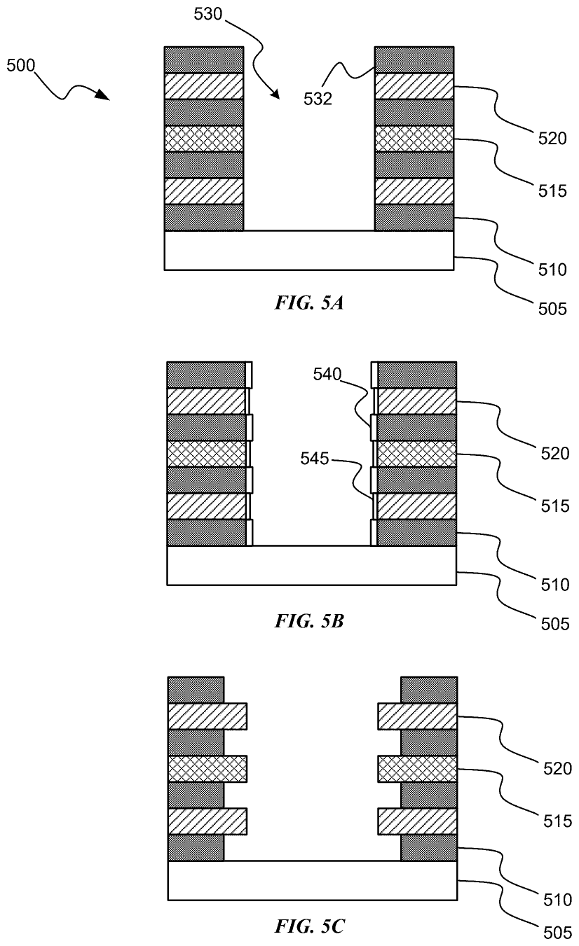

FIGS. 5A-5C show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D devices to 3D devices, many process operations are modified from vertical to horizontal operations. Additionally, as 3D structures grow in the number of cells being formed, the aspect ratios of features, such as holes or trenches, and other structures increase, sometimes dramatically. During 3D device processing, stacked layers of alternating materials may be formed on a substrate. After the features are formed through the stacked layers on the substrate, some of the layers may be recessed relative to other layers. However, as the aspect ratios of features continue to increase, as well as a length or depth of the features, etchants may have difficulties in diffusing the length or depth of the features. This may result in non-uniform etching of individual layers along the length or depth of the features.

Many conventional technologies utilize metal-containing precursors to assist the etchants in being able to travel the length or depth of the features. However, the use of metal-containing precursors results in contamination of the structure. As devices continue to scale, sensitivity to metal-containing residue increases. As such, the use of metal-containing precursors to assist the etchants in being able to travel the length or depth of the features and the resultant contamination of the structure through metal-containing residue impacts final device performance. Other etching methods, such as metal-free etching methods, may not be able to reach lower portions of the features, again resulting in non-uniform etching of individual layers along the length or depth of the features.

The present technology overcomes these issues by performing a dry etch process which may selectively etch silicon-and-oxygen-containing material laterally, while limiting etching of other exposed materials, including other silicon-containing materials. By utilizing particular precursor combinations, such as a catalyst precursor and an etchant precursor, silicon-and-oxygen-containing material may be etched laterally while exposed surfaces of other exposed materials may be maintained during the etch process. In this way, the present technology may allow etching operations to be performed that may not remove or may only minimally remove underlying structure materials that are to be maintained during recessing of silicon-and-oxygen-containing material.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in one or more chambers separated from the fabrication system shown in different embodiments. It will be appreciated that additional configurations of deposition, etching, annealing, and curing chambers for dielectric films are contemplated by system 100.

FIG. 2A shows a cross-sectional view of an exemplary process chamber system 200 with partitioned plasma generation regions within the processing chamber, and which may be configured to perform processes as described further below. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system 201 may optionally be included in the system, and may process a first gas which then travels through gas inlet assembly 205. The inlet assembly 205 may include two or more distinct gas supply channels where the second channel may bypass the RPS 201, if included.

A cooling plate 203, faceplate 217, ion suppressor 223, showerhead 225, and a pedestal 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215.

Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205. In some embodiments, additional plasma sources may be utilized including inductively-coupled plasma sources extending about the chamber or in fluid communication with the chamber, as well as additional plasma-generating systems.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiOx:SiNx etch ratios, SiOx:Si etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHZ frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

The chambers discussed previously may be used in performing exemplary methods including etching methods. Turning to FIG. 4, exemplary operations in a method 400 according to embodiments of the present technology are shown. Prior to the first operation of the method 400, a substrate may be processed in one or more ways before being placed within a processing region of a chamber in which method 400 may be performed. For example, stacked layers may be formed on the substrate and then one or more memory holes or trenches may be formed through the stacked layers. The stacked layers may include any number of materials, and may include alternating layers of a placeholder material and a dielectric material. In embodiments the dielectric material may be or include a silicon-and-oxygen-containing material, such as silicon oxide material, and the placeholder material may be or include one or more silicon-containing materials, such as silicon material, silicon-and-nitrogen-containing material, and silicon-and-germanium-containing material. That is, the placeholder material may include multiple different materials throughout the stacked layers. Although the remaining disclosure will discuss silicon oxide material and silicon material, silicon nitride material, and silicon germanium material, any other known materials used in these layers may be substituted for one or more of the layers. A hole or trench may be formed through the stacked layers that may extend to the level of the substrate, which may provide an exposed portion of the substrate at the bottom of the hole or trench. In this way, within the hole or trench structure, there may be exposed regions of the stacked layers as well as the substrate itself. Some or all of these operations may be performed in chambers or system tools as previously described, or may be performed in different chambers on the same system tool, which may include the chamber in which the operations of method 400 are performed.

The hole or trench, which may also be referred to as a feature, may be characterized by a depth of greater than or about 2 μm, and may be characterized by a depth of greater than or about 2.5 μm, greater than or about 3 μm, greater than or about 3.5 μm, greater than or about 4 μm, greater than or about 4.5 μm, greater than or about 5 μm, greater than or about 5.5 μm, greater than or about 6 μm, or more. In embodiments, an aspect ratio height-to-width ratio of the hole or trench, also referred to as feature, may be greater than or about 2:1, greater than or about 3:1, greater than or about 4:1, greater than or about 5:1, greater than or about 10:1, greater than or about 20:1, greater than or about 30:1, greater than or about 40:1, greater than or about 50:1, or more.

The method 400 may include flowing a catalyst precursor to a processing region of a semiconductor processing chamber at operation 405. An exemplary chamber may be chamber 200 previously described. The catalyst precursor may be provided prior to an etchant precursor, as further discussed below, to increase selectivity of etching silicon-and-oxygen-containing material on the substrate relative to other silicon-containing materials.

The catalyst precursor may include at least one hydrogen-containing functional group. In embodiments, the catalyst precursor may be or include an alcohol, such that the catalyst precursor may include at least one hydroxyl (—OH) group. In embodiments, the catalyst precursor may include a plurality of —OH groups. That is, the catalyst precursor may be or include polyols, such as a diol, a triol, or other alcohol-containing material. In embodiments, the catalyst precursor may be or include alkyl, such that the catalyst precursor may include at least one alkyl group. In embodiments, the catalyst precursor may be or include a thiol, such that the catalyst precursor may include one or more sulfhydryl (—SH) groups. In embodiments, the catalyst precursor may be or include an amine, such that the catalyst precursor may include a basic nitrogen atom with a lone pair. For example, the catalyst precursor may be or include a primary amine or a secondary amine. It is contemplated that additional materials may be used as the catalyst precursors so long as the material includes a hydrogen atom that may be given to the silicon-and-oxygen-material, such that the catalyst precursor may be adsorbed by the silicon-and-oxygen-material.

The catalyst precursor may be characterized by a reduced vapor pressure, such that the catalyst precursor is able to diffuse along an entire length or depth of the hole or feature through the stacked layers. In embodiments, the catalyst precursor may be characterized by a vapor pressure, measured at a temperature between about 0° C. and about 30° C., of less than or about 100 Torr, and may be characterized by a vapor pressure of less than or about 90 Torr, less than or about 80 Torr, less than or about 70 Torr, less than or about 60 Torr, less than or about 50 Torr, less than or about 40 Torr, less than or about 30 Torr, less than or about 20 Torr, less than or about 20 Torr, less than or about 10 Torr, less than or about 5 Torr, less than or about 1 Torr, less than or about 750 mTorr, less than or about 500 mTorr, less than or about 250 mTorr, less than or about 100 mTorr, less than or about 50 mTorr, less than or about 10 mTorr, less than or about 5 mTorr, or less.

In embodiments, the catalyst precursor may be metal-free. Additionally, the processing region may be maintained free of precursors containing metal during operation 405, as well as subsequent operations of method 400 discussed below. Conventional technologies may utilize metal-containing precursors to improve selectivity and other etch properties. However, the use of metal-containing precursors may leave metal-containing residue within the structure being processed. As such, the present technology, in using metal-free catalyst precursors, may prevent metal contamination of the structure.

Exemplary catalyst precursors provided at operation 405 may be or include, but are not limited to, isopropanol (C₃H₈O), 1-propanol (C₃H₇OH), isobutanol (C₄H₁₀O), ethenol (C₂H₄O), ethylene glycol (C₂H₆O₂), or any other material that includes a hydrogen atom that may be given to the silicon-and-oxygen-material, such that the catalyst precursor may be adsorbed by the silicon-and-oxygen-material. The catalyst precursors provided at operation 405 may additionally or alternatively be or include partially fluorinated and/or chlorinated alcohols and diols. For example, the catalyst precursors may be or include, but are not limited to, C₂F₄O₂H₂, fluorinated ethylene glycol, fluorinated isobutanol, fluorinated ethenol, and CF₂═CF—OH.

At operation 410, method 400 may include contacting the substrate with the catalyst precursor. The contacting may adsorb the catalyst precursor on exposed regions of the stacked layers as well as the substrate itself within the hole or trench structure. While the catalyst precursor may adsorb on all exposed materials, a degree of adsorption on silicon-and-oxygen-containing material may be stronger than other exposed materials. Without being bound to any particular theory, it is believed a hydrogen atom may be given to exposed material, such as to an oxygen atom of the silicon-and-oxygen-containing material. Subsequent etching, as further discussed below, may then preferentially break Si—O bonds over other bonds in the structure and result in selective etching of silicon-and-oxygen-containing material.

The contacting at operation 410 may be continued for a first period of time. The first period of time may be sufficient to provide desired catalyst adsorption, while limiting residence time that may begin to affect other material surfaces. For example, in some embodiments the first period of time may be greater than or about 0.5 seconds, and may be greater than or about 1 second, greater than or about 1.5 seconds, greater than or about 2 seconds, greater than or about 2.5 seconds, greater than or about 3 seconds, greater than or about 3.5 seconds, greater than or about 4 seconds, greater than or about 4.5 seconds, greater than or about 5 seconds, greater than or about 10 seconds, greater than or about 20 seconds, greater than or about 30 seconds, greater than or about 45 seconds, greater than or about 60 seconds, or more. However, to limit additional effects, in some embodiments the first period of time may be less than or about 60 seconds, and may be less than or about 45 seconds, less than or about 30 seconds, less than or about 20 seconds, less than or about 10 seconds, less than or about 5 seconds, less than or about 4.5 seconds, less than or about 4 seconds, less than or about 3.5 seconds, less than or about 3 seconds, less than or about 2.5 seconds, less than or about 2 seconds, less than or about 1.5 seconds, less than or about 1 second, less than or about 0.5 seconds, or less.

Subsequent to the first period of time, a flow of the catalyst precursor may be halted at optional operation 415. A purge may then be performed at optional operation 420, which may remove residual catalyst precursor or other materials from the processing region of the semiconductor processing chamber. The purge may be performed with any number of materials that may be chemically inert, such as nitrogen or noble gases, which may be used to purge the processing region of the semiconductor processing chamber. The purging process may improve etch selectivity by expediting removal of excess catalyst material, which may begin to adsorb to a greater degree on the other exposed materials and ultimately may affect etch selectivity. This may facilitate the lateral etching of the silicon-and-oxygen-containing material while reducing exposure and impact on the other exposed materials.

The method 400 may include providing the etchant precursor to the processing region of the semiconductor processing chamber at operation 425. The etchant precursor may be any precursor able to etch silicon-and-oxygen-containing material. In embodiments, the etchant precursor may be or include a halogen-containing precursor. For example, the etchant precursor may include one or more of fluorine, chlorine, bromine, or iodine. The etchant precursor may include other elements, such as hydrogen, nitrogen, sulfur, silicon, or any other material so long as the precursor is able to etch silicon-and-oxygen-containing material. In embodiments, the etchant precursor may be or include, but is not limited to, hydrogen fluoride (HF) or HF-pyridine.

In embodiments, the etchant precursor may be provided to a remote plasma region of the semiconductor processing chamber. Again, an exemplary chamber may be chamber 200 previously described, which may include one or both of the RPS unit 201 or first plasma region 215. Either or both of these regions may be the remote plasma region used in operation 425. A plasma may be generated within the remote plasma region, which may generate plasma effluents of the etchant precursor. The plasma effluents may be flowed to the processing region of the chamber. However, it is also contemplated that plasma effluents may not be formed, and method 400 may be a thermal process where the processing region is maintained plasma-free during the entirety of method 400.

By utilizing a remote plasma in embodiments where plasma effluents of the etchant precursor may be formed, a relatively lower plasma power may be used, such as below or about 5 kW, below or about 3 kW, below or about 1 kW, below or about 500 W, below or about 400 W, below or about 300 W, below or about 200 W, below or about 100 W, or less, which may limit the energy of the plasma effluents, as well as limit the full dissociation of etchant precursor. Additionally, by forming a remote plasma, which may include ion filtering prior to delivery to the substrate as explained above, the extent to which the ion plasma effluents interact with the structure may be limited. For example, a local plasma may retain sufficient energy at the wafer level and may result in damage to upper portions of the structure through a bombardment process. Additionally, ion effluents often have a directionality, which may benefit anisotropic etching for surfaces normal to the direction of effluent delivery, but may not facilitate lateral etching. The present technology may utilize neutral or radical species produced in the plasma to produce an isotropic etch, which may laterally etch the silicon-and-oxygen-containing material.

At operation 430, method 400 may include contacting the substrate with the etchant precursor or, if formed, the plasma effluents thereof. The contacting may result in the etchant precursor or, if formed, the plasma effluents thereof interacting with all exposed materials on the substrate. While the etchant precursor or, if formed, the plasma effluents thereof may interact with all exposed materials on the substrate, the previously adsorbed catalyst precursor may result in the etchant precursor or, if formed, the plasma effluents thereof selectively interacting with silicon-and-oxygen-containing material relative to other exposed materials on the substrate. The selective interaction with silicon-and-oxygen-containing material may result in the contacting selectively removing the silicon-and-oxygen-containing material relative to other exposed materials on the substrate. Without being bound to any particular theory, it is believed etchant material, such as a fluorine atom from a fluorine-containing etchant precursor, may go to exposed material, such as to a silicon atom of the silicon-and-oxygen-containing material and may break an Si—O bond. Additionally, a hydrogen atom, which may be in the etchant precursor, may simultaneously attach to the oxygen atom of the Si—O bond to result in etching. In utilizing the catalyst precursor followed by the etchant precursor or, if formed, plasma effluents thereof, the removal of the silicon-and-oxygen-containing material may be solid byproduct-free. This may obviate the need for a flash operation to clear or clean the hole or trench of etch byproduct material.

Additionally, the present technology may result in the contacting selectively removes the silicon-and-oxygen-containing material uniformly along a length of the one or more features. The etching of each layer of silicon-and-oxygen-containing material along the length of the one or more features may be characterized by a uniformity of greater than or about 80%. Uniformity may be measured by comparing an etch amount of individual layers of the silicon-and-oxygen-containing material at opposite ends, such as an uppermost layer and a bottommost layer, of the feature. In embodiments, the etching of each layer of silicon-and-oxygen-containing material along the length of the one or more features may be characterized by a uniformity of greater than or about 85%, greater than or about 90%, greater than or about 92%, greater than or about 95%, greater than or about 96%, greater than or about 98%, greater than or about 99%, greater than or about 99.5%, or more.

The contacting at operation 430 may be continued for a second period of time. The second period of time may be sufficient to provide desired etching of silicon-and-oxygen-containing material, while limiting residence time that may begin to affect other material surfaces. For example, in some embodiments the second period of time may be greater than or about 0.5 seconds, and may be greater than or about 1 second, greater than or about 1.5 seconds, greater than or about 2 seconds, greater than or about 2.5 seconds, greater than or about 3 seconds, greater than or about 3.5 seconds, greater than or about 4 seconds, greater than or about 4.5 seconds, greater than or about 5 seconds, greater than or about 10 seconds, greater than or about 20 seconds, greater than or about 30 seconds, greater than or about 45 seconds, greater than or about 60 seconds, or more. However, to limit additional effects, in some embodiments the second period of time may be less than or about 60 seconds, and may be less than or about 45 seconds, less than or about 30 seconds, less than or about 20 seconds, less than or about 10 seconds, less than or about 5 seconds, less than or about 4.5 seconds, less than or about 4 seconds, less than or about 3.5 seconds, less than or about 3 seconds, less than or about 2.5 seconds, less than or about 2 seconds, less than or about 1.5 seconds, less than or about 1 second, less than or about 0.5 seconds, or less.

In embodiments, the second period of time may be the same as or different from the first period of time. For example, the second period of time may be longer than the first period of time to allow catalyst material or, if formed, plasma effluents of the catalyst material to permeate the formed hole or trench.

Subsequent to the second period of time, a flow of the etchant precursor may be halted. A purge may then be performed, which may remove residual etchant precursor or other materials from the processing region of the semiconductor processing chamber. The purge may be performed with any number of materials that may be chemically inert, such as nitrogen or noble gases, which may be used to purge the processing region of the semiconductor processing chamber. The purging process may improve etch selectivity by expediting removal of excess etchant material, which may begin to etch other exposed materials on the substrate and ultimately may affect etch selectivity. This may facilitate the lateral etching of the silicon-and-oxygen-containing material while reducing exposure and impact on the other exposed materials.

By performing the operations of method 400 as described above, an etch selectivity of silicon-and-oxygen-containing material relative to other exposed materials, such as silicon material, silicon-and-nitrogen-containing material, and silicon-and-germanium-containing material may be greater than or about 3:1, and may be greater than or about 4:1, greater than or about 5:1, greater than or about 10:1 greater than or about 15:1, greater than or about 20:1, greater than or about 30:1, greater than or about 50:1, greater than or about 70:1, greater than or about 100:1, or higher.

By performing an amount of catalyst adsorption followed by an amount of etch, a controlled lateral or isotropic etch of silicon-and-oxygen-containing material may be performed. To further facilitate controlled etching, the present technology may be performed in a number of cycles to refresh the catalyst, allow the removal of etch byproducts, and/or facilitate delivery of etchants into the lateral recesses being formed. In embodiments, operations of method 400, including repeatedly contacting the substrate with the catalyst precursor and the etchant precursor, for greater than or about two cycles, greater than or about three cycles, greater than or about four cycles, greater than or about five cycles, greater than or about ten cycles, greater than or about twenty cycles, greater than or about fifty cycles, greater than or about 100 cycles, greater than or about 200 cycles, or more cycles, depending on factors such as the extent of silicon-and-oxygen-containing material etching to be performed, or other effects of the process. By repeatedly contacting the substrate with the catalyst precursor and the etchant precursor, the silicon-and-oxygen-containing material may be removed on a layer-by-layer basis, similar to an atomic layer etching (ALE) process.

In embodiments, an etch rate of the silicon-and-oxygen-containing material per cycle is greater than or about 0.05 angstrom per cycle (Å/cycle), and may be greater than or about 0.1 Å/cycle, greater than or about 0.15 Å/cycle, greater than or about 0.2 Å/cycle, greater than or about 0.25 Å/cycle, greater than or about 0.3 Å/cycle, greater than or about 0.35 Å/cycle, greater than or about 0.4 A/cycle, greater than or about 0.45 Å/cycle, greater than or about 0.5 Å/cycle, greater than or about 0.55 Å/cycle, greater than or about 0.6 Å/cycle, greater than or about 0.65 Å/cycle, greater than or about 0.7 Å/cycle, greater than or about 0.75 Å/cycle, greater than or about 0.8 Å/cycle, greater than or about 0.85 Å/cycle, greater than or about 0.9 Å/cycle, greater than or about 1 Å/cycle, or more. By limiting the etch rate per cycle, a precise control may be maintained and the silicon-and-oxygen-containing material may be removed on a layer-by-layer basis.

Process conditions may also impact the operations performed in method 400. Each of the operations of method 400 may be performed during a constant temperature in embodiments, while in some embodiments the temperature may be adjusted during different operations. Temperatures may be maintained in any range, however, at higher temperatures, the catalyst precursor may vaporize and may not readily adsorb on exposed materials on the structure. As adsorption decreases, exposed materials other than silicon-and-oxygen-containing material may begin to etch more readily, and the selectivity may be reduced. Additionally, the etchant precursor may not be drawn along an entire length or depth of the hole or trench, resulting in a non-uniform etch along the length or depth of the hole or trench. Accordingly, in some embodiments the temperature may be maintained at less than or about 200° C., and may be maintained at less than or about 150° C., less than or about 125° C., less than or about 100° C., less than or about 90° C., less than or about 80° C., less than or about 70° C., less than or about 60° C., less than or about 50° C., less than or about 40° C., less than or about 30° C., less than or about 20° C., less than or about 10° C., or less. In embodiments, the temperature may at least be partially dependent on the vapor pressure of the catalyst precursor.

In some embodiments, the process may occur at a variety of pressures, which may facilitate operations in any of a number of process chambers. For example, the process may be performed within chambers capable of providing pressures less than or about 1 Torr, and may be maintained at less than or about 900 mTorr, less than or about 800 mTorr, less than or about 700 mTorr, less than or about 300 mTorr, less than or about 200 mTorr, less than or about 100 mTorr, less than or about 75 mTorr, less than or about 50 mTorr, or less. Additionally, the pressure within the chamber may be maintained at higher pressures, which may increase the etch rate, and the pressure within the processing chamber may be maintained at greater than or about 50 mTorr, and may be maintained at greater than or about 75 mTorr, greater than or about 100 mTorr, greater than or about 200 mTorr, greater than or about 300 mTorr, greater than or about 400 mTorr, greater than or about 500 mTorr, greater than or about 600 mTorr, greater than or about 700 mTorr, greater than or about 800 mTorr, greater than or about 900 mTorr, greater than or about 1 Torr, or more.

Turning to FIGS. 5A-5C, cross-sectional views of a structure 500 being processed according to some embodiments of the present technology are illustrated. As illustrated in FIG. 5A, substrate 505 may have a plurality of stacked layers overlying the substrate 505, which may be silicon, silicon germanium, or other substrate materials. The stacked layers may include a silicon-and-oxygen-containing material 510 in alternation with one or more silicon-containing materials, such as a silicon-and-nitrogen-containing material 515 and/or a silicon-and-germanium-containing material 520. While illustrated with two silicon-containing materials, the silicon-and-nitrogen-containing material 515 and the silicon-and-germanium-containing material 520, it is contemplated that the structure 500 may include just silicon-and-nitrogen-containing material 515 or the silicon-and-germanium-containing material 520. Alternatively, the one or more silicon-containing materials may be silicon material. Although illustrated with only seven layers of material, exemplary structures may include any numbers of layers previously discussed, and it is to be understood that the figures are only schematics to illustrate aspects of the present technology. Hole or trench 530, which may be a memory hole, may be defined through the stacked layers to the level of substrate 505. Hole or trench 530 may be defined by sidewalls 532 that may be composed of the stacked layers on the substrate 505.

In FIG. 5B, the structure is illustrated after operations according to the present technology, such as method 400, have begun to be performed, such as discussed with respect to FIG. 4 above. A catalyst precursor may have been provided to a processing region of a semiconductor processing chamber, and the substrate 505 may have been contacted with the catalyst precursor. The contacting may adsorb the catalyst precursor on the silicon-and-oxygen-containing material 510 to form a catalyzed portion of the silicon-and-oxygen-containing material 540. Additionally, contacting may adsorb the catalyst precursor on the one or more silicon-containing materials to form a catalyzed portion of the one or more silicon-containing materials 545, including the silicon-and-nitrogen-containing material 515 and/or the silicon-and-germanium-containing material 520. As illustrated in FIG. 5B and as discussed with regard to method 400, an amount of catalyst adsorbed on the silicon-and-oxygen-containing material 510 may be greater than an amount of catalyst adsorbed on the one or more silicon-containing materials, such as the silicon-and-nitrogen-containing material 515 and/or the silicon-and-germanium-containing material 520 as well as substrate 505 or other silicon material that may be exposed.

In FIG. 5C, the structure is illustrated after additional operations according to the present technology, such as method, have been performed, such as discussed with respect to FIG. 4 above. An etchant precursor may have been provided to a processing region of a semiconductor processing chamber, and the substrate 505 may have been contacted with the etchant precursor or, if formed, plasma effluents thereof. The contacting may remove the silicon-and-oxygen-containing material 510. The contacting may selectively remove the silicon-and-oxygen-containing material 510 relative to other exposed materials on the substrate 505. By utilizing precursors and operations as discussed throughout the present technology, the silicon-and-oxygen-containing material 510 may be isotropically or laterally etched from between adjacent layers of one or more silicon-containing materials, such as silicon material, silicon-and-nitrogen-containing material, and silicon-and-germanium-containing material, while limiting the damage or removal of the one or more silicon-containing materials.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a catalyst precursor to a processing region of a semiconductor processing chamber, wherein a substrate is disposed within the processing region, and wherein the substrate comprises a silicon-and-oxygen-containing material and one or more silicon-containing materials;
contacting the substrate with the catalyst precursor, wherein the contacting adsorbs the catalyst precursor on the silicon-and-oxygen-containing material and/or the one or more silicon-containing materials;
providing an etchant precursor to the processing region; and
contacting the substrate with the etchant precursor, wherein the contacting selectively removes the silicon-and-oxygen-containing material.

2. The semiconductor processing method of claim 1, wherein the catalyst precursor comprises an alcohol.

3. The semiconductor processing method of claim 1, wherein the catalyst precursor is characterized by a vapor pressure of less than or about 100 Torr at a temperature between about 0° C. and about 30° C.

4. The semiconductor processing method of claim 1, wherein the catalyst precursor comprises isopropanol (C₃H₈O), 1-propanol (C₃H₇OH), isobutanol (C₄H₁₀O), ethenol (C₂H₄O), ethylene glycol (C₂H₆O₂), C₂F₄O₂H₂, fluorinated ethylene glycol, fluorinated isobutanol, fluorinated ethenol, or CF₂═CF—OH.

5. The semiconductor processing method of claim 1, wherein the catalyst precursor is metal-free.

6. The semiconductor processing method of claim 1, wherein the silicon-containing materials comprise silicon material, silicon-and-nitrogen-containing material, and silicon-and-germanium-containing material.

7. The semiconductor processing method of claim 1, wherein the substrate comprises a plurality of layers of the silicon-and-oxygen-containing material in alternation with a plurality of layers of the one or more silicon-containing materials.

8. The semiconductor processing method of claim 1, wherein the etchant precursor comprises a halogen-containing precursor.

9. The semiconductor processing method of claim 1, wherein the etchant precursor comprises hydrogen fluoride (HF) or HF-pyridine.

10. The semiconductor processing method of claim 1, wherein removing the silicon-and-oxygen-containing material is solid byproduct-free.

11. The semiconductor processing method of claim 1, wherein contacting the substrate with the etchant precursor removes the silicon-and-oxygen-containing material relative to the one or more silicon-containing materials at a selectivity of greater than or about 3:1.

12. The semiconductor processing method of claim 1, further comprising:
repeatedly contacting the substrate with the catalyst precursor and the etchant precursor to remove the silicon-and-oxygen-containing material on a layer-by-layer basis.

13. The semiconductor processing method of claim 1, wherein a temperature within the processing region is maintained at less than or about 150° C.

14. A semiconductor processing method comprising:
providing a catalyst precursor to a processing region of a semiconductor processing chamber, wherein a substrate is disposed within the processing region, wherein the substrate comprises a plurality of layers of silicon-and-oxygen-containing material in alternation with a plurality of layers of one or more silicon-containing materials, and wherein the plurality of layers of silicon-and-oxygen-containing material and the plurality of layers of one or more silicon-containing materials define one or more features;
contacting the substrate with the catalyst precursor, wherein the contacting adsorbs the catalyst precursor on the plurality of layers of silicon-and-oxygen-containing material and the plurality of layers of one or more silicon-containing materials;
halting a flow of the catalyst precursor;
providing an etchant precursor to the processing region; and
contacting the substrate with the etchant precursor, wherein the contacting selectively removes the plurality of layers of silicon-and-oxygen-containing material uniformly along a length of the one or more features.

15. The semiconductor processing method of claim 14, wherein the catalyst precursor is characterized by a vapor pressure of less than or about 100 Torr at a temperature between about 0° C. and about 30° C.

16. The semiconductor processing method of claim 14, wherein the one or more features are characterized by a depth of greater than or about 2 μm.

17. The semiconductor processing method of claim 14, wherein a temperature within the processing region is maintained at less than or about 100° C.

18. A semiconductor processing method comprising:
providing a metal-free catalyst precursor comprising at least one hydrogen-containing functional group to a processing region of a semiconductor processing chamber, wherein a substrate is disposed within the processing region, wherein the substrate comprises a plurality of layers of silicon-and-oxygen-containing material in alternation with a plurality of layers of one or more silicon-containing materials, and wherein the plurality of layers of silicon-and-oxygen-containing material and the plurality of layers of one or more silicon-containing materials define one or more features;
contacting the substrate with the metal-free catalyst precursor, wherein the contacting adsorbs the metal-free catalyst precursor on the plurality of layers of silicon-and-oxygen-containing material and the plurality of layers of one or more silicon-containing materials;
halting a flow of the metal-free catalyst precursor;
providing a halogen-containing precursor to the processing region;
contacting the substrate with the halogen-containing precursor, wherein the contacting selectively removes the plurality of layers of silicon-and-oxygen-containing material uniformly along a length of the one or more features; and
repeatedly contacting the substrate with the metal-free catalyst precursor and the halogen-containing precursor for a number of cycles to remove the plurality of layers of silicon-and-oxygen-containing material on a layer-by-layer basis.

19. The semiconductor processing method of claim 18, wherein the one or more features are characterized by an aspect ratio of greater than or about 5:1.

20. The semiconductor processing method of claim 18, wherein an etch rate of the plurality of layers of silicon-and-oxygen-containing material is greater than or about 0.05 angstrom per cycle (Å/cycle).
